(19) United States
(12) Patent Application Publication
(10) Pub. No.: US 2003/0186479 A1
(43) Pub. Date: Oct. 2, 2003

(54) Zn3P2-ZnO mixture thin film for photoluminescence and method of fabricating the same

(76) Inventors: Young-Chang Kim, Seoul (KR); Sang-Yeol Lee, Seoul (KR)

Correspondence Address: LEE & HONG, 801 SOUTH FIQUEROA STREET, 14TH FLOOR, LOS ANGELES, CA, 90017, US

(21) Appl. No.: 10/161,904

(22) Filed: Jun. 4, 2002

(30) Foreign Application Priority Data
Mar. 27, 2002 (KR) 2002-16765

(51) Int. Cl. H01L 21/00; H01L 21/44; H01L 21/4763

(52) U.S. Cl. 438/46; 438/642; 438/607

(57) ABSTRACT

The present invention discloses a Zn₃P₂—ZnO mixture thin film for photoluminescence and a method of fabricating the same. The object of the present invention is to provide a Zn₃P₂—ZnO mixture thin film for photoluminescence and a method of fabricating the same which can generate the photoluminescence characteristics in a navy blue region by depositing a semiconductor mixture thin film of ZnO and Zn₃P₂ with a predetermined mole ratio on the upper surface of a sapphire substrate by pulsed laser deposition. According to the Zn₃P₂—ZnO mixture thin film for photoluminescence and the method of fabricating the same, a thin film having a flat surface property and the effective photoluminescence characteristics of a navy blue region can be fabricated by growing a thin film of a mixture material on a sapphire substrate by a deposition method using laser ablation by using a target of a mixture of ZnO and Zn₃P₂ having a mole ratio of 1:9. The PLD is being widely used as a deposition method of multicomponent compounds because it reduces the possibility of contamination by impurities and the composition of a thin film almost agrees with that of a target. In the present invention, the mixture ratio of a thin film material can be controlled by using the PLD and controlling the mixture ratio of the target material. As the result, a thin film for photoluminescence having a flat surface and a strong navy blue light emission can be obtained, and such a result can be used for a fluorescent material for a light emitting device very effectively and practically.

### BACKGROUND OF THE INVENTION

1. Field of the Invention

The present invention relates to a Zn₃P₂-ZnO mixture thin film for photoluminescence and a method of fabricating the same, and more particularly, to a Zn₃P₂-ZnO mixture thin film for photoluminescence, which is formed by depositing a semiconductor mixture thin film of ZnO and Zn₃P₂ with a predetermined mole ratio on the upper surface of a sapphire substrate by pulsed laser deposition, and a method of fabricating the same.

2. Description of the Related Art

In our technical world displays have an important function as human interfaces for making abstract information available through visualization. In the past, many applications for displays were identified and realized, each with its own specific requirements. Therefore, different display technologies have been developed, each having their own strengths and weaknesses with respect to the requirements of particular display applications, thus making a particular display technology best suited for a particular class of applications.

Light emitting diodes(LED) which emit light spontaneously under forward bias conditions have various fields of application such as indicator lamps, devices of visual displays, light sources for an optical data link, optical fiber communication, etc.

In the majority of applications, either direct electronic band-to-band transitions or impurity-induced indirect band-to-band transitions in the material forming the active region of the LED are used for light generation. In these cases, the energy gap of the material chosen for the active region of the LED, i.e. the zone where the electronic transitions responsible for the generation of light within the LED take place, determines the color of a particular LED.

A further known concept for tailoring the energy of the dominant optical transition of a particular material and thus the wavelength of the generated light is the incorporation of impurities leading to the introduction of deep traps within the energy gap. In this case, the dominant optical transition may take place between a band-state of the host material and the energy level of the deep trap. Therefore, the proper choice of an impurity may lead to optical radiation with photon energies below the energy gap of the host semiconductor.

Today, exploiting these two concepts for tailoring the emission wavelength of an LED and using III-V or II-VI compound semiconductors or their alloys for the active region of the LED, it is possible to cover the optical spectrum between near infrared and blue with discrete emission lines.

Blue light emitting MIS diodes have been realized in the GaN system. Examples of these have been published in:

“Violet luminescence of Mg-doped GaN” by H. P. Maruska et al., Applied Physics Letters, Vol. 22, No. 6, pp. 303-305, 1973,

“Blue-Green Numeric Display Using Electroluminescent GaN” by J. I. Pankove, RCA Review, Vol. 34, pp. 336-343, 1973,

“Electric characteristics of GaN: Zn MIS-type light emitting diode” by M. R. H. Khan et al., Physica B 185, pp. 480-484, 1993,

“GaN electroluminescent devices: preparation and studies” by G. Jacob et al., Journal of Luminescence, Vol. 17, pp. 263-282, 1978,

EP-0-579 897 A1: “Light-emitting device of gallium nitride compound semiconductor”.

Unfortunately, the present-day LEDs suffer from numerous deficiencies. Light emission in the LED is spontaneous, and, thus, is limited in time on the order of 1 to 10 nanoseconds. Therefore, the modulation speed of the LED is also limited by the spontaneous lifetime of the LED.

Attempts were made to improve the performance of the LEDs. For example, a short wavelength blue semiconductor light emitting device has been developed. The compound semiconductor device of gallium nitrite series such as GaN, InGaN, GaAlN, InGaAlN has been recently considered as a material of the short wavelength semiconductor light emitting device.

For example, in the semiconductor light emitting device using GaN series material, a room temperature pulse oscillation having wavelength of 380 to 417 nm is confirmed.

However, in the semiconductor laser using GaN series material, a satisfying characteristic cannot be obtained, a threshold voltage for a room temperature pulse oscillation ranges from 10 to 40V, and the variation of the value is large.

This variation is caused by difficulty in a crystal growth of the compound semiconductor layer of gallium nitride series, and large device resistance. More specifically, there cannot be formed the compound semiconductor layer of p-type gallium nitride series having a smooth surface and high carrier concentration. Moreover, since contact resistance of a p-side electrode is high, a large voltage drop is generated, so that the semiconductor layer is deteriorated by a heat generation and a metal reaction even when the pulse oscillation is operated. In consideration of a cheating value, the room temperature continuous oscillation cannot be achieved unless the threshold voltage is reduced to less than 10V.

Moreover, when a current necessary to the laser generation is implanted, the high current flows locally and a carrier cannot be uniformly implanted to an active layer, and an instantaneous breakage of the device occurs. As a result, the continuous generation of the laser cannot be achieved.

In the light-emitting device of GaN series, since the p-side electrode contract resistance was high, the operating voltage was increased. Moreover, nickel, serving as a p-side electrode metal, and gallium forming the p-type semiconductor layer, were reacted with each other, melted, and deteriorated at an electrical conduction. As a result, it was difficult to continuously generate the laser.

Besides, SiC and ZnO are known as short wavelength light emitting materials.

However, SiC and ZnO are disadvantageous in that the chemical crystalline thereof is very unstable or a crystal growth itself is difficult for SiC and ZnO to be used as compounds semiconductors required for blue light emission. In case of SiC, it is chemically stable, but the lifetime and brightness thereof are low for SiC to be put into practical use.

Meanwhile, in case of ZnO, it is proper material for blue light emission and shorter wavelength light emission since it has a characteristic similar to GaN. Moreover, ZnO has an excitation binding energy (e.g., 60 meV) about three times larger than that of GaN, it is judged to be a very proper material for short wavelength light element of the next generation.

Nevertheless, even though there was a case where ZnO was manufactured as a p-n junction, the light emission efficiency thereof was very low and thus the availability thereof as an actual device is very low, and it is difficult for ZnO to form a p-type material.

### SUMMARY OF THE INVENTION

It is, therefore, an object of the present invention to provide a Zn₃P₂—ZnO mixture thin film for photoluminescence, which can generate photoluminescence characteristics in a navy blue region by depositing a semiconductor mixture thin film of ZnO and Zn₃P₂ with a predetermined mole ratio on the upper surface of a sapphire substrate by pulsed laser deposition, and a method of fabricating the same.

To achieve the above object, there is provided a method of fabricating a Zn₃P₂ZnO mixture thin film in accordance with a preferred embodiment of the present invention, which enables photoluminescence in a navy blue region by depositing a semiconductor mixture thin film of ZnO and Zn₃P₂ with a predetermined mole ratio on the upper surface of a base substrate.

Preferably, there is provided a mixture thin film of ZnO and Zn₃P₂ which is fabricated by the above fabrication method.

More preferably, there is provided a method of fabricating a mixture thin film of ZnO and Zn₃P₂ in which the mixture thin film of ZnO and Zn₃P₂ is deposited on a sapphire substrate by pulsed laser deposition (PLD)

### BRIEF DESCRIPTION OF THE DRAWINGS

The above objects, features and advantages of the present invention will become more apparent from the following detailed description when taken in conjunction with the accompanying drawings, in which:

FIG. 1 is a view illustrating the constitution of a Zn₃P₂—ZnO mixture thin film for photoluminescence in accordance with a first embodiment of the present invention;

FIG. 2 is a photograph observing the surface of a Zn₃P₂—ZnO mixture thin film for photoluminescence by means of a scanning electron microscope in accordance with the first embodiment of the present invention; and

FIG. 3 is a graph illustrating photoluminescence characteristics of the Zn₃P₂ZnO mixture thin film for photoluminescence in accordance with the first embodiment of the present invention;

### DETAILED DESCRIPTION OF THE PREFERRED EMBODIMENT

A preferred embodiment of the present invention will now be described with reference to the accompanying drawings.

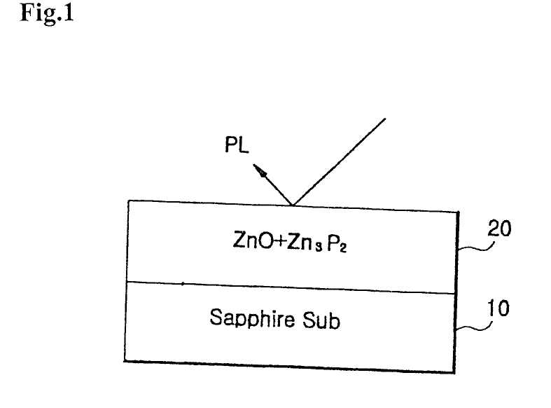

FIG. 1 is a view illustrating the constitution of a Zn₃P₂—ZnO mixture thin film for photoluminescence in accordance with a first embodiment of the present invention.

Referring to this, the present invention discloses a thin film, which has a flat surface property and shows PL(Photoluminescence) characteristics of a navy blue region by depositing a thin film 20, on a sapphire substrate (Al₂O₃) 10 by a deposition method using laser ablation, and a method of fabricating the same, the thin film 20 being formed as a target material which is a mixture of ZnO and Zn₃P₂ with a mole ratio of 1:9, the ZnO being a II-VI group semiconductor having a hexagonal wurtzite structure, a wide bandgap of 3.37 eV and a direct transition property and the Zn₃P₂ being a II3-V2 group semiconductor having a zincblend structure, a bandgap of 1.5 eV and the same direct transition property.

For this, in the present invention, when fabricating the mixture thin film 20 of ZnO and Zn₃P₂, PLD (Pulsed Laser Deposition) is preferably used in controlling the mole ratio of each target material for mixture and depositing the mixture thin film on the upper surface of the sapphire substrate (Al₂O₃).

More specifically, the above PLD is being widely used as a deposition method of multicomponent compounds because it reduces the possibility of contamination by impurities and the composition of a thin film almost agrees with that of a target. In the present invention, the mixture ratio of a thin film material can be controlled by using the PLD and controlling the mixture ratio of the target material.

Hereinafter, the characteristics of the PLD will be described. A PLD apparatus has a plurality of target holders and substrate holders for depositing a multi-layer thin film in a chamber filled with vacuum or reaction gas. The target holder and the substrate holder are designed to control intervals between each other.

As an external energy source for vaporizing a material to thus deposit a thin film, a high power laser is used. Such a laser is supplied in the form of pulses in order to avoid an excessive increase of temperature in the target material and produce a laser of a high strength. In addition, the target holder is designed to rotate at a constant speed. The rotation of the target inhibits an excessive increase of temperature in the target to thus inhibit splashing (which is a phenomenon in which a target surface is ablated to be separated, not in the form of fine materials such as atoms, ions, etc., but in a lump of the target material, resultantly forming undesired particles on the substrate surface.)

A laser beam, which is focused on the target surface through a series of optical apparatuses, produces a state of plasma (or plume), said plasma being an assembly of emitted particles in the form of flashing light consisting of electrons, ions, atoms, molecules and the like emitted from the target surface, and this plume forms a thin film having a crystal structure on a substrate that is heated at a temperature suitable for crystallization.

The PLD has a simple structure, a high growth rate of a thin film and has a very high kinetic energy (200-400 eV) of particles emitted from the target, so it is capable of crystallization even at a low substrate temperature and can easily reproduce the composition of a multicomponent compound target on a deposited thin film.

The process for forming a thin film will be described by the following four fields.

(1) Interaction Between Laser Beam and Target

This occurs when laser phonons are absorbed by electrons of atoms constituting a solid material or a lattice structure of the solid material. By the thusly absorbed energy, the electrons are excited to a high energy state. At this time, a surface temperature is increased depending on the optical absorption coefficient, heat diffusion coefficient and laser pulse width of the material.

(2) Interaction Between Vaporized Material and Laser

When vaporization is started from the target, a laser beam is scattered by the vaporized material and the laser energy is absorbed by the same. The temperature of free electrons is increased to thus accelerate the electrons, and the ionization ratio of particles is increased by collision among evaporated particles. When the vicinity of the target surface is heated at a high temperature, ions are emitted from the target by thermonic emission.

(3) Anisotropic-Type Adiabatic Expansion of Plasma

A high-pressure layer with a very high particle density is formed near the target. Particles are emitted in the direction vertical to the target surface and form a plume of the plasma state which generates bright light. Since the amount of light absorbed by the plasma depends on the density of the plasma, the absorption coefficient is rapidly reduced as the plasma expands.

(4) Growth of Thin Film

The plasma is composed of various particles such as gaseous ions, neutral atoms, molecular clusters, etc. Since there is no electric field, there are no accelerated ions. In addition, a lot of ions are incident upon the substrate in the form of intermittent pulses. The representative theories on the deposition of the thin film of the above state include two-dimensional layer-by-layer growth (Frank-van der Merwe Growth), three-dimensional island growth (Volmer-Weber Growth), two-dimensional layer-by-layer growth followed by three-dimensional islanding (Stranski-Krastanov Growth), etc.

In the present invention, a thin film is formed by depositing it for about twelve minutes using the above deposition principle, so the composition of the target almost agrees with that of the thin film. Moreover, the composition of the thin film can be controlled so that the composition of ZnO and Zn₃P₂ has a mole ratio of 1:9 by controlling the composition of the target.

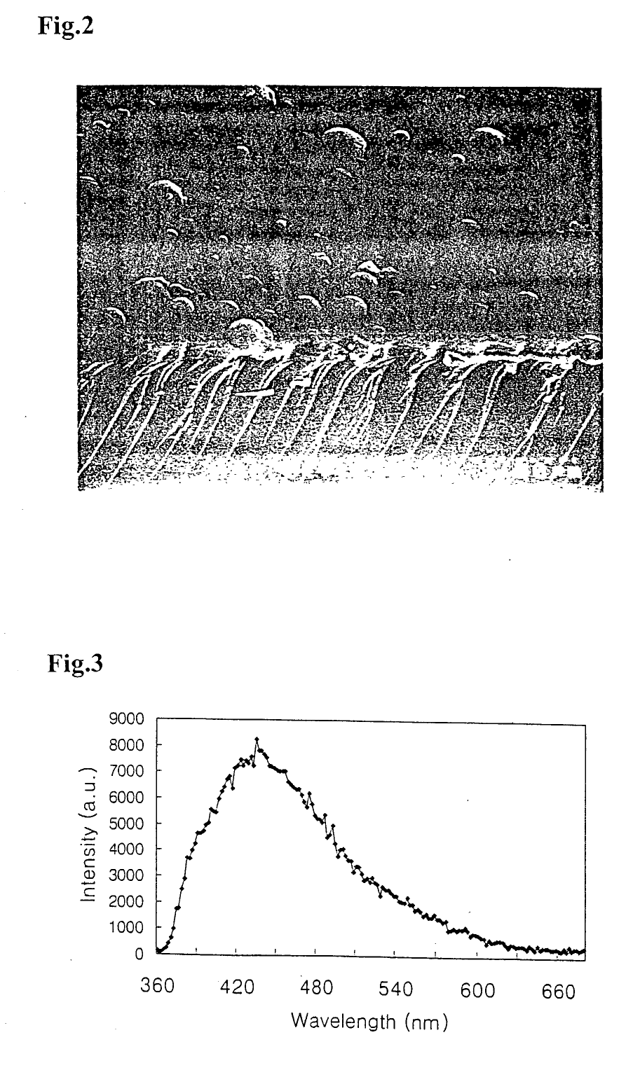

FIG. 2 is a photograph observing the surface of a Zn₃P₂—ZnO mixture thin film for photoluminescence by means of a scanning electron microscope in accordance with the first embodiment of the present invention.

Referring to this, as the result of observing the surface of the Zn₃P₂—ZnO mixture thin film for photoluminescence in accordance with the first embodiment of the present invention, the thickness of the thin film is estimated to be 5000 Å in consideration of its sloping degree of about 40 degrees, and the deposition rate thereof is found to be 41.67 nm/min considering that the thin film is deposited for about twelve minutes.

In addition, through an electronic microscope, it is found that a droplet having an average surface radius of 600 Å is formed but the overall surface of the thin film is very flat.

FIG. 3 is a graph illustrating photoluminescence characteristics of the Zn₃P₂ZnO mixture thin film for photoluminescence in accordance with the first embodiment of the present invention.

Referring to this, in FIG. 3 illustrating the photoluminescence (PL) characteristics of the surface of a deposited mixture thin film 20, it is found that the thin film 20 exhibits photoluminescence characteristic having a half-width of 114 nm with its center at 440 nm. The photoluminescence characteristics of the wavelength corresponding to the navy blue light emitting region are very strong, so it is possible to observe navy blue light with naked eyes. Thus, the mixture thin film 20 for photoluminescence in accordance with the present invention is applicable as a fluorescent material for navy blue light emission.

While the invention has been shown and described with reference to certain preferred embodiments thereof, it will be understood by those skilled in the art that various changes in form and details may be made therein without departing from the spirit and scope of the invention as defined by the appended claims.

As described above, according to the Zn₃P₂—ZnO mixture thin film for photoluminescence and the method of fabricating the same in accordance with the present invention, a thin film having a flat surface property and the effective photoluminescence characteristics of a navy blue region can be fabricated by growing a thin film of a mixture material on a sapphire substrate by a deposition method using laser ablation by using a target of a mixture of ZnO and Zn₃P₂ having a mole ratio of 1:9. The PLD is being widely used as a deposition method of multicomponent compounds because it reduces the possibility of contamination by impurities and the composition of a thin film almost agrees with that of a target. In the present invention, the mixture ratio of a thin film material can be controlled by using the PLD and controlling the mixture ratio of the target material. As the result, a thin film for photoluminescence having a flat surface and a strong navy blue light emission can be obtained, and such a result can be used for a fluorescent material for a light emitting device very effectively and practically.

What is claimed is:

1. A method of fabricating a Zn₃P₂—ZnO mixture thin film, which enables photoluminescence in a navy blue region by depositing a semiconductor mixture thin film of ZnO and Zn₃P₂ with a predetermined mole ratio on the upper surface of a base substrate.

2. A mixture thin film of ZnO and Zn₃P₂, which is fabricated by the method of claim 1.

3. The method of claim 1, wherein the mixture thin film of ZnO and Zn₃P₂ is deposited on a sapphire substrate by pulsed laser deposition (PLD).
